(19) United States
(12) Patent Application Publication
(10) Pub. No.: US 2020/0211668 A1
(43) Pub. Date: Jul. 2, 2020

(54) SHIFT REGISTER AND METHOD THEREOF

(71) Applicant: INT TECH CO., LTD., HSINCHU COUNTY (TW)

(72) Inventor: SHIH-SONG CHENG, KAOHSIUNG CITY (TW)

(21) Appl. No.: 16/235,411

(22) Filed: Dec. 28, 2018

(51) Int. Cl. G11C 19/18; G11C 19/28

(52) U.S. Cl. CPC G11C 19/184; G11C 19/28

(57) ABSTRACT

A circuit includes: an input circuit stage arranged to receive an input pulse signal during a first phase; an output circuit stage coupled to the input circuit stage for generating an output pulse signal during a second phase following the first phase according to a first clock signal; and an auxiliary circuit stage coupled to the input circuit stage and the output circuit stage for keeping the output pulse signal on a predetermined voltage level during a third phase following the second phase according to a second clock signal different from the first clock signal.

### PRIORITY CLAIM AND CROSS-REFERENCE

### Background

A shift register is used to perform operations such as data registering, delay or conversion of serial and parallel output for input binary data. For example, when applied in OLEDs (Organic Light Emitting Diode) driver circuits, the shift registers are utilized for sequentially providing pulse signals to a plurality of data output terminals according to a clock signal, such that data driving signals or gate driving signals can be outputted line-by-line for driving corresponding pixels.

### SUMMARY

Embodiments of the present invention provide a circuit comprising an input circuit stage, an output circuit stage, and an auxiliary circuit stage. The input circuit stage is arranged to receive an input pulse signal during a first phase. The output circuit stage is coupled to the input circuit stage for generating an output pulse signal during a second phase following the first phase according to a first clock signal. The auxiliary circuit stage is coupled to the input circuit stage and the output circuit stage for keeping the output pulse signal on a predetermined voltage level during a third phase following the second phase according to a second clock signal different from the first clock signal.

In an embodiment, the input pulse signal has a first pulse with a first pulse width in the first phase, the first clock signal has a second pulse with a second pulse width in the second phase, and the second pulse width is equal to the first pulse width.

In an embodiment, the first clock signal has a first pulse with a first pulse width in the second phase, the output pulse signal has a second pulse with a second pulse width in the second phase, and the second pulse width is equal to the first pulse width.

In an embodiment, the first clock signal has a first pulse with a first pulse width in the second phase, the second clock signal has a second pulse with a second pulse width in the third phase, and the second pulse width is equal to the first pulse width.

In an embodiment, the circuit further comprises a capacitive device coupled between the output circuit stage and the input circuit stage.

In an embodiment, the circuit further comprises a capacitive device coupled between the auxiliary circuit stage and a reference voltage.

In an embodiment, the input circuit stage comprises: a first transistor, having a controlling terminal receiving the input pulse signal, a first connecting terminal coupled to the controlling terminal, and a second connecting terminal coupled to the output stage; and a second transistor, having a controlling terminal receiving the input pulse signal, a first connecting terminal coupled to a reference voltage, and second connecting terminal coupled to the auxiliary circuit stage.

In an embodiment, the output circuit stage comprises: a third transistor, having a controlling terminal coupled to the second connecting terminal of the first transistor, a first connecting terminal receiving the first clock signal, and a second connecting terminal for outputting the output pulse signal; and a fourth transistor, having a controlling terminal coupled to the second connecting terminal of the third transistor, a first connecting terminal coupled to the reference voltage, and a second connecting terminal coupled to the auxiliary circuit stage.

In an embodiment, the output circuit stage further comprises: a capacitive device, having a first terminal coupled to the controlling terminal of the third transistor, and a second terminal coupled to the second connecting terminal of the third transistor.

In an embodiment, the auxiliary circuit stage comprises: a fifth transistor, having a controlling terminal receiving the second clock signal, a first connecting terminal coupled to the controlling terminal, and a second connecting terminal coupled to the second connecting terminal of the fourth transistor; a sixth transistor, having a controlling terminal coupled to the second connecting terminal of the fifth transistor, a first connecting terminal coupled to the reference voltage, and a second connecting terminal coupled to the controlling terminal of the third transistor; and a seventh transistor, having a controlling terminal coupled to the second connecting terminal of the fifth transistor, a first connecting terminal coupled to the reference voltage, and a second connecting terminal coupled to the second connecting terminal of the third transistor.

In an embodiment, the auxiliary circuit stage further comprises: a capacitive device, having a first terminal coupled to the controlling terminal of the sixth transistor, and a second terminal coupled to the reference voltage.

Embodiments of the present invention provide a shift register comprising a first circuit and a second circuit. The first circuit is arranged to generate a first output pulse signal according to an input pulse signal, a first clock signal, and a second clock signal. The first circuit comprises: a first input circuit stage, arranged to receive the input pulse signal during a first phase; a first output circuit stage, coupled to the first input circuit stage for generating the first output pulse signal during a second phase following the first phase according to the first clock signal; and a first auxiliary circuit stage, coupled to the first input circuit stage and the first output circuit stage for keeping the first output pulse signal on a predetermined voltage level during a third phase following the second phase according to the second clock signal different from the first clock signal. The second circuit is arranged to generate a second output pulse signal according to the fist output pulse signal, the first clock signal, and the second clock signal.

In an embodiment, the second circuit comprises: a second input circuit stage, arranged to receive the first output pulse signal during the second phase; a second output circuit stage, coupled to the second input circuit stage for generating the second output pulse signal during the third phase following the second phase according to the first clock signal; and a second auxiliary circuit stage, coupled to the second input circuit stage and the second output circuit stage for keeping the second output pulse signal on the predetermined voltage level during a fourth phase following the third phase according to the second clock signal different.

In an embodiment, the first input circuit stage comprises: a first transistor, having a controlling terminal receiving the input pulse signal, a first connecting terminal coupled to the controlling terminal, and a second connecting terminal coupled to the first output stage; and a second transistor, having a controlling terminal receiving the input pulse signal, a first connecting terminal coupled to a reference voltage, and second connecting terminal coupled to the first auxiliary circuit stage.

In an embodiment, the first output circuit stage comprises: a third transistor, having a controlling terminal coupled to the second connecting terminal of the first transistor, a first connecting terminal receiving the first clock signal, and a second connecting terminal for outputting the first output pulse signal; and a fourth transistor, having a controlling terminal coupled to the second connecting terminal of the third transistor, a first connecting terminal coupled to the reference voltage, and a second connecting terminal coupled to the first auxiliary circuit stage.

In an embodiment, the first auxiliary circuit stage comprises: a fifth transistor, having a controlling terminal receiving the second clock signal, a first connecting terminal coupled to the controlling terminal, and a second connecting terminal coupled to the second connecting terminal of the fourth transistor; a sixth transistor, having a controlling terminal coupled to the second connecting terminal of the fifth transistor, a first connecting terminal coupled to the reference voltage, and a second connecting terminal coupled to the controlling terminal of the third transistor; and a seventh transistor, having a controlling terminal coupled to the second connecting terminal of the fifth transistor, a first connecting terminal coupled to the reference voltage, and a second connecting terminal coupled to the second connecting terminal of the third transistor.

Embodiments of the present invention provide a method comprising: arranging an input circuit stage to receive an input pulse signal during a first phase; arranging an output circuit stage for generating an output pulse signal according to a first clock signal during a second phase following the first phase; and arranging an auxiliary circuit stage for keeping the output pulse signal on a predetermined voltage level according to a second clock signal different from the first clock signal during a third phase following the second phase.

In an embodiment, the method further comprises: arranging a capacitive device to couple between the output circuit stage and the input circuit stage.

In an embodiment, the method further comprises: arranging a capacitive device to couple between the auxiliary circuit stage and a reference voltage.

In an embodiment, the input pulse signal has a first pulse with a first pulse width in the first phase, the first clock signal has a second pulse with a second pulse width in the second phase, and the second pulse width is equal to the first pulse width.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram illustrating a shift register in accordance with some embodiments of the present invention.

FIG. 2 is a diagram illustrating a registering circuit in accordance with some embodiments of the present invention.

FIG. 3 is a timing diagram illustrating signal waveforms of a registering circuit in accordance with some embodiments.

FIG. 4A is a diagram illustrating a registering circuit during the first phase in accordance with some embodiments.

FIG. 4B is a timing diagram illustrating the signal waveforms of a registering circuit during the first phase in accordance with some embodiments.

FIG. 5A is a diagram illustrating a registering circuit during the second phase in accordance with some embodiments.

FIG. 5B is a timing diagram illustrating the signal waveforms of a registering circuit during the second phase in accordance with some embodiments.

FIG. 6A is a diagram illustrating a registering circuit during the third phase in accordance with some embodiments.

FIG. 6B is a timing diagram illustrating the signal waveforms of a registering circuit during the third phase in accordance with some embodiments.

FIG. 7 is a diagram illustrating the leakage current of a transistor in accordance with some embodiments.

FIG. 8 is a diagram illustrating a registering circuit in accordance with some embodiments of the present invention.

FIG. 9A is a diagram illustrating a registering circuit during the second phase in accordance with some embodiments.

FIG. 9B is a timing diagram illustrating the signal waveforms of a registering circuit during the second phase in accordance with some embodiments.

FIG. 10A is a diagram illustrating a registering circuit during the third phase in accordance with some embodiments.

FIG. 10B is a timing diagram illustrating the signal waveforms of a registering circuit during the third phase in accordance with some embodiments.

FIG. 11 is a flowchart illustrating a method for generating an output pulse signal in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the term “about” generally means within 10%, 5%, 1%, or 0.5% of a given value or range. Alternatively, the term “about” means within an acceptable standard error of the mean when considered by one of ordinary skill in the art. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the term “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

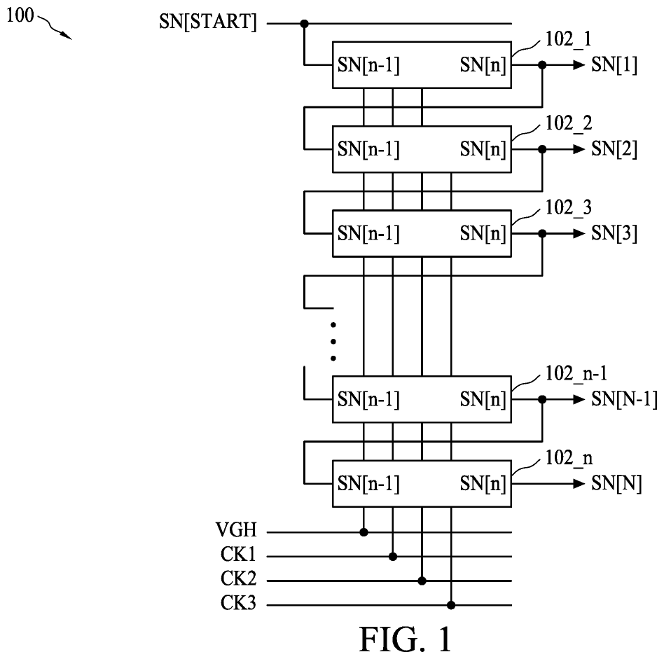

FIG. 1 is a diagram illustrating a shift register 100 in accordance with some embodiments of the present invention. The shift register 100 may be a gate driver on array (GOA) circuit of a display panel system. The shift register 100 comprises a plurality of registering circuits 102_1-102_n. The registering circuits 102_1-102_n are connected in series. For example, the output terminal of the first registering circuit 102_1 is connected to the input terminal of the second registering circuit 102_2. According to some embodiments, each of the registering circuits 102_1-102_n is controlled by a first clock signal CK1, a second clock signal CK2, and a third clock signal CK3. A supply power (not shown) is arranged to provide a reference voltage VGH to each of the registering circuits 102_1-102_n. According to some embodiments, the reference voltage VGH is a relatively high voltage. In addition, during the operation, the first registering circuits 102_1 is arranged to receive an initial input signal SN[START], the initial input signal SN[START] may be a periodical pulse signal with a predetermined period and a predetermined pulse width. The predetermined pulse width may be smaller than or equal to one line-time. The line-time may be the period of a clock signal with a predetermined frequency. For example, the line-time may be the access time of a row of memory units by using the clock signal. The first registering circuit 102_1 is arranged to output a first output pulse signal SN[1] with respect to the initial input signal SN[START]. The first output pulse signal SN[1] is a time shifted pulse signal of the initial input signal SN[START]. According to some embodiments, the first output pulse signal SN[1] is shifted/delayed by one line-time with respect to the initial input signal SN[START]. The second output pulse signal SN[2] is a time shifted pulse signal of the first output pulse signal SN[1]. The third output pulse signal SN[3] is a time shifted pulse signal of the second output pulse signal SN[2], and so on. In other words, the phase difference between two adjacent/consecutive output pulse signals (e.g. SN[2] and SN[3]) is one line-time. The output pulse signals SN[1]-SN[n] may be arranged to control a plurality of OLED (Organic Light Emitting Diode) rows, for example. The clock signals CK1, CK2, and CK3 have the same duty cycle and the same period. The pulse width of the clock signals CK1, CK2, and CK3 may be smaller than or equal to one line-time. According to some embodiments, the second clock signal CK2 is shifted/delayed by one line-time with respect to the first clock signal CK1, and the third clock signal CK3 is shifted/delayed by one line-time with respect to the second clock signal CK2.

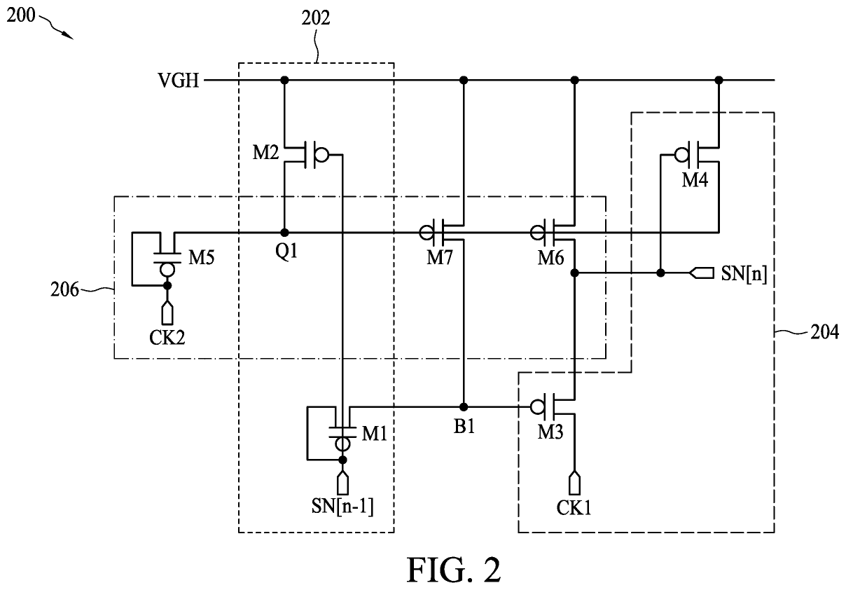

FIG. 2 is a diagram illustrating a registering circuit 200 in accordance with some embodiments of the present invention. The registering circuit 200 may be the implementation of each of the registering circuits 102_1-102_n. For brevity, the detailed description of the registering circuit 200 is described in accordance with the registering circuit 102_n. Other registering circuits 102_1-102_n−1 may have the similar structures and operations, and the detailed description is omitted here for brevity. The registering circuit 200 comprises an input circuit stage 202, an output circuit stage 204, and an auxiliary circuit stage 206.

According to some embodiments, the input circuit stage 202 is arranged to receive an input pulse signal SN[n−1] during a first phase. The output circuit stage 204 is coupled to the input circuit stage 202 for generating an output pulse signal SN[n] during a second phase following the first phase according to a first clock signal CK1. The auxiliary circuit stage 206 is coupled to the input circuit stage 202 and the output circuit stage 204 for keeping the output pulse signal SN[n] on a predetermined voltage level VGH, e.g. the supply voltage level, during a third phase following the second phase according to a second clock signal CK2 different from the first clock signal CK1. During the first phase, i.e. the receiving phase, the input circuit stage 202 is enabled to receive the input pulse signal SN[n−1] while the auxiliary circuit stage 206 is disabled. During the first phase, the output circuit stage 204 may be partially enabled to output the previous output pulse signal. During the second phase, i.e. the outputting phase, the output circuit stage 204 is enabled to output the output pulse signal SN[n] while the input circuit stage 202 and the auxiliary circuit stage 206 are disabled. During the third phase, the auxiliary circuit stage 206 is enabled to keep the output pulse signal SN[n] on the predetermined voltage level VGH while the input circuit stage 202 and the output circuit stage 206 are disabled.

According to some embodiments, the input circuit stage 202 comprises a first transistor M1 and a second transistor M2. The transistors M1 and M2 may be P-channel metal-oxide-semiconductor field-effect transistor (P-type MOSFET). The transistor M1 has a controlling terminal, e.g. the gate, receiving the input pulse signal S[n−1], a first connecting terminal, e.g. the drain, coupled to the controlling terminal, and a second connecting terminal (i.e. the terminal B1), e.g. the source, coupled to the output stage 204. The transistor M2 has a controlling terminal, e.g. the gate, receiving the input pulse signal S[n−1], a first connecting terminal, e.g. the source, coupled to the predetermined voltage level VGH, and a second connecting terminal (i.e. the terminal Q1), e.g. the drain, coupled to the auxiliary circuit stage 206.

The output circuit stage 204 comprises a first transistor M3 and a second transistor M4. The transistors M3 and M4 may be the P-type MOSFET. The transistor M3 a controlling terminal, e.g. the gate, coupled to the source terminal of the transistor M1, a first connecting terminal, e.g. the source, receiving the first clock signal CK1, and a second connecting terminal, e.g. the drain, for outputting the output pulse signal S[n]. The transistor M4 has a controlling terminal, e.g. the gate, coupled to the drain of the transistor M3, a first connecting terminal, e.g. the source, coupled to the predetermined voltage level VGH, and a second connecting terminal, e.g. the drain, coupled to the auxiliary circuit stage 206.

The auxiliary circuit stage 206 comprises a first transistor M5, a second transistor M6, and a third transistor M7. The transistors M5, M6, and M7 may be the P-type MOSFET. The transistor M5 has a controlling terminal, e.g. the gate, receiving the second clock signal CK2, a first connecting terminal, e.g. the drain, coupled to the gate, and a second connecting terminal, e.g. the source, coupled to the drain of the transistor M4. The transistor M6 has a controlling terminal, e.g. the gate, coupled to the source of the transistor M5, a first connecting terminal, e.g. the source, coupled to the predetermined voltage level VGH, and a second connecting terminal, e.g. the drain, coupled to the drain of the transistor M3. The transistor M7 has a controlling terminal, e.g. the gate, coupled to the source of the transistor M5, a first connecting terminal, e.g. the source, coupled to the predetermined voltage level VGH, and a second connecting terminal, e.g. the drain, coupled to the gate of the transistor M3.

According to some embodiments, the transistor M1-M7 may also be N-type MOSFETs, which also belongs to the scope of the present invention.

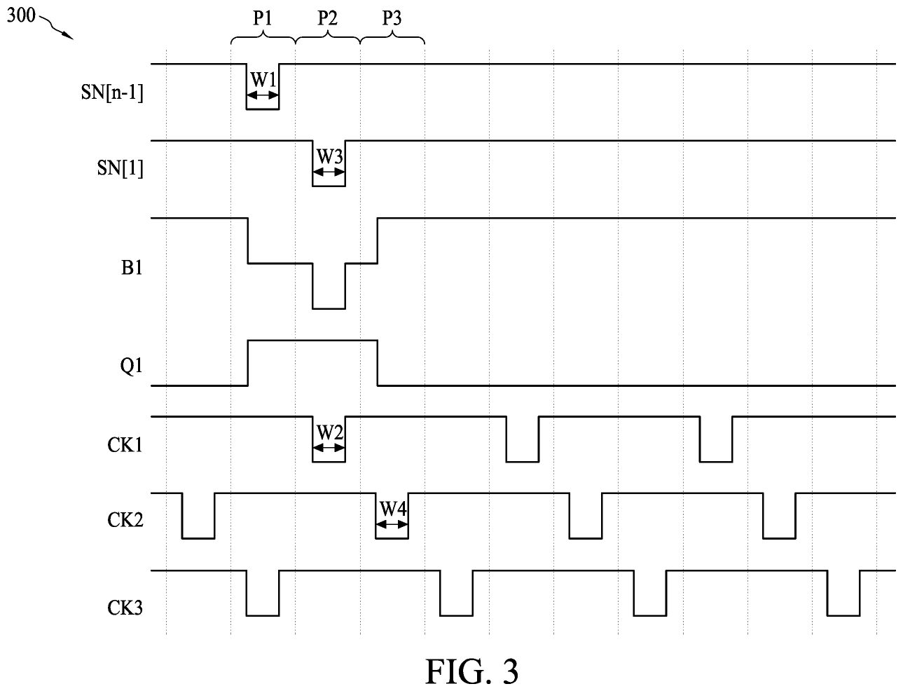

FIG. 3 is a timing diagram illustrating signal waveforms 300 of the registering circuit 200 in accordance with some embodiments. The signal waveforms comprise the input pulse signal SN[n−1], the output pulse signal S[N], the signal on the terminal B1, the signal on the terminal Q1, the first clock signal CK1, the second clock signal CK2, and the third clock signal CK3. The phases P1, P2, and P3 are three consecutive phases in time domain.

According to some embodiments, the input pulse signal SN[n−1] has a pulse with a pulse width W1 in the first phase P1. The first clock signal CK1 has a pulse with a pulse width W2 in the second phase P2. The pulse width W2 is equal to the pulse width W1. The output pulse signal SN[n] has a pulse with a pulse width W3 in the second phase P2, and the pulse width W3 is equal to the pulse width W2. The second clock signal CK2 has a pulse with a pulse width W4 in the third phase P3, and the pulse width W4 is equal to the pulse width W2.

The first phase P1 may be regarded as a receiving phase. The second phase P2 may be regarded as an outputting phase. The third phase P3 may be regarded as a maintaining phase. For simplicity, during the first phase P1, the pulse of the input pulse signal SN[n−1] is inputted to the registering circuit 200. During the second phase P2, the pulse of the output pulse signal SN[n] is outputted from the registering circuit 200. During the third phase P3, the voltage level of the output pulse signal SN[n] is kept on a relatively high voltage level, e.g. the predetermined voltage level VGH. According to some embodiments, the pulse of the third clock signal CK3 is aligned/synchronized with the pulse of the input pulse signal SN[n−1] during the first phase P1. The pulse of the first clock signal CK1 is aligned/synchronized with the pulse of the output pulse signal SN[n] during the second phase P2. The pulse of the second clock signal CK2 is arranged to resume/restore the voltage levels on the terminals B1 and Q1 into the default/predetermined/initial voltage levels for keeping the voltage level of the output pulse signal SN[n] on the predetermined voltage level VGH during the third phase P3.

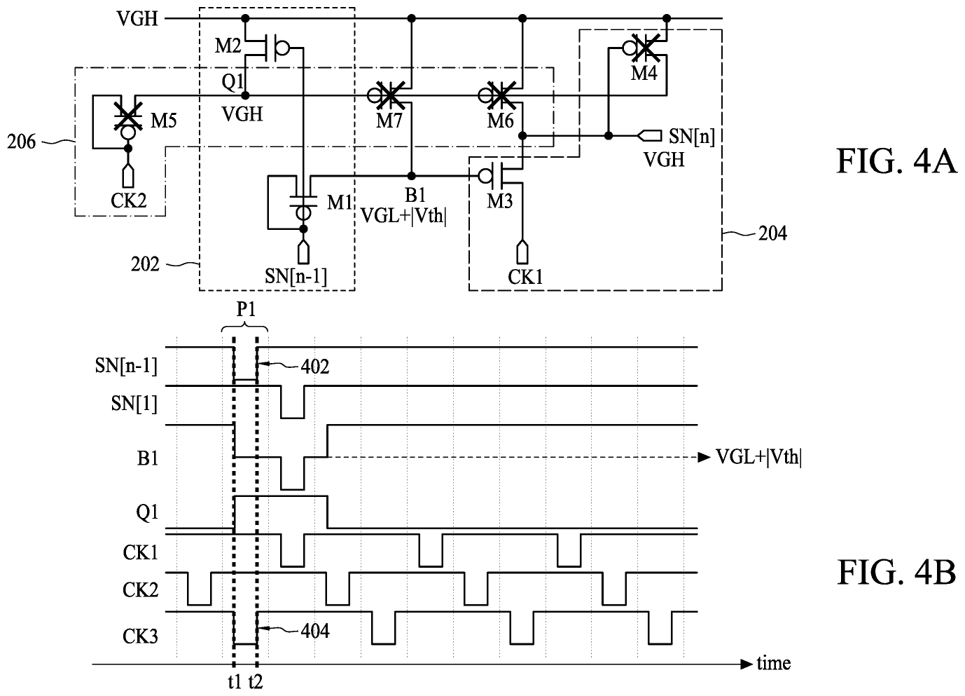

FIG. 4A is a diagram illustrating the registering circuit 200 during the first phase P1 in accordance with some embodiments. FIG. 4B is a timing diagram illustrating the signal waveforms of the registering circuit 200 during the first phase P1 in accordance with some embodiments. During the first phase P1 of the registering circuit 200, the registering circuit 200 is arranged to receive the pulse 402 of the input pulse signal SN[n−1]. According to some embodiments, the pulse 402 is aligned with the pulse 404 of the third clock signal CK3. During the first phase P1, a relatively low voltage level, e.g. the ground voltage VGL, of the pulse 402 may turn on the transistors M1 and M3 at time t1. When the transistor M1 is turned on, the voltage level on the terminal B1 is discharged to the relatively low voltage level, e.g. the voltage level VGL+|Vth|, from the relatively high voltage level, e.g. the predetermined voltage level VGH, wherein Vth is the threshold voltage of a transistor, and the transistor may be M1, M2, M3, M4, M5, or M7. When the transistor M3 is turned on, the high voltage level VGH of the first clock signal CK1 is transmitted to the output terminal, i.e. the drain of transistor M3, to make the voltage level of the output pulse signal SN[n] to keep on the high voltage level VGH. In addition, the low voltage level of the pulse 402 also turns on the transistor M2 at time t1. When the transistor M2 is turned on, the voltage level on the terminal Q1 is charged to the high voltage level VGH from the low voltage level VGL to turn off the transistors M6 and M7. According to some embodiments, at time t2 of the first phase P1, the voltage levels of the input pulse signal SN[n−1] and the third clock signal CK3 are changed to the high voltage level VGH from the low voltage level VGL. The transistors M4 and M5 may be turned off during the first phase P1.

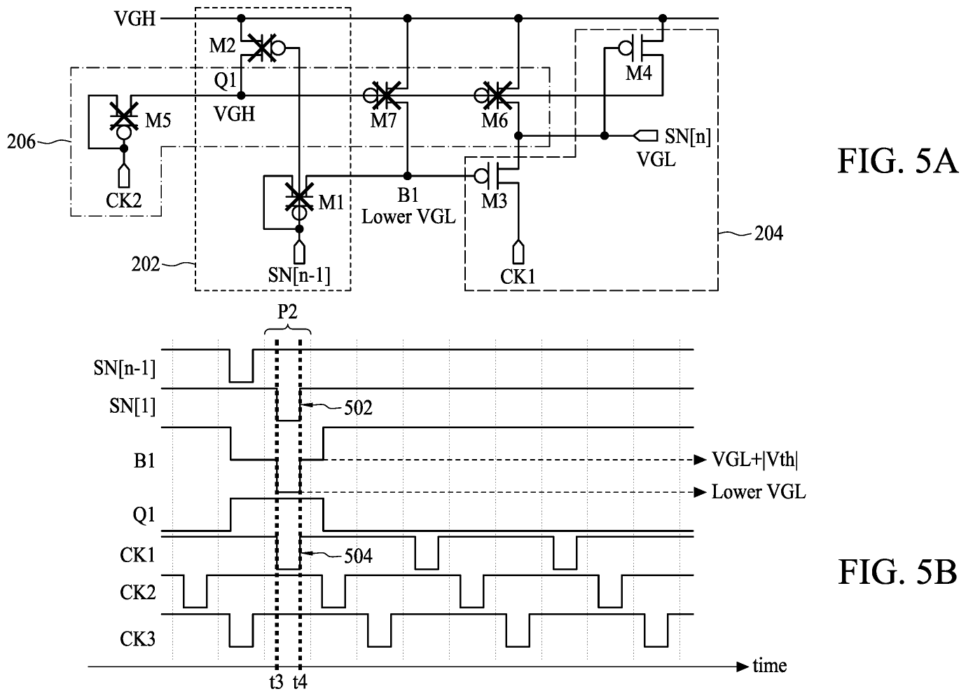

FIG. 5A is a diagram illustrating the registering circuit 200 during the second phase P2 in accordance with some embodiments. FIG. 5B is a timing diagram illustrating the signal waveforms of the registering circuit 200 during the second phase P2 in accordance with some embodiments. During the second phase P2 of the registering circuit 200, the registering circuit 200 is arranged to output the pulse 502 of the output pulse signal SN[n]. According to some embodiments, the pulse 502 is aligned with the pulse 504 of the first clock signal CK1. During the second phase P2, the high voltage level VGH of the input pulse signal SN[n−1] may turn off the transistor M1 at time t3. When the transistor M1 is turned off, the terminal B1 is floating, i.e. the voltage level on the terminal B1 is kept on the low voltage level, i.e. VGL+|Vth|, to continue turning on the transistor M3 before the time t3. At time t3, when the voltage level of the first clock signal CK1 changes to the low voltage level VGL from the high voltage level VGH, the voltage level of the output pulse signal SN[n] is discharged to the low voltage level VGL from the high voltage level VGH. In addition, at time t3, when the voltage level of the first clock signal CK1 changes to the low voltage level VGL, the voltage level on the terminal B1 is further discharged to a voltage level lower than VGL (i.e. the lower VGL) from the voltage level VGL+|Vth|. Moreover, when the voltage level of the first clock signal CK1 changes to the low voltage level VGL at time t3, the transistor M4 is turned on to charge the terminal Q1. Therefore, the voltage level on the terminal Q1 may be kept on the high voltage level VGH to continue turning off the transistors M6 and M7 during the phase P2. According to some embodiments, at time t4 of the second phase P2, the voltage levels of the output pulse signal SN[n] and the first clock signal CK1 are changed to the high voltage level VGH from the low voltage level VGL, and the voltage level on the terminal B1 is changed to the voltage level VGL+|Vth| from the voltage level lower than VGL. The transistors M2 and M5 may be turned off during the second phase P2.

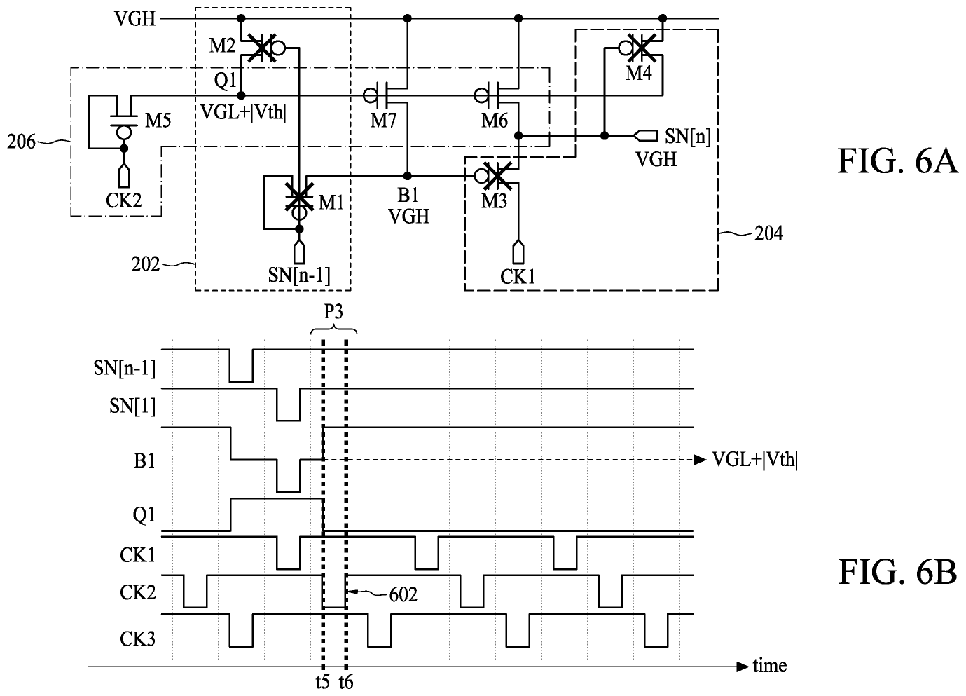

FIG. 6A is a diagram illustrating the registering circuit 200 during the third phase P3 in accordance with some embodiments. FIG. 6B is a timing diagram illustrating the signal waveforms of the registering circuit 200 during the third phase P3 in accordance with some embodiments. During the third phase P3 of the registering circuit 200, the registering circuit 200 is arranged to keep the voltage level of the output pulse signal SN[n] on the high voltage level VGH for a specific time, e.g. a line-time. During the third phase P3, the pulse 602 of the second clock signal CK2 discharges the voltage level on the terminal Q1 to the low voltage level VGL+|Vth| for ensuring the voltage level of the output pulse signal SN[n] kept on the high voltage level VGH. Specifically, during the third phase P3, the voltage level of the second clock signal CK2 is changed to the low voltage level VGL from the high voltage level VGH to turn on the transistor M5 at time t5. When the transistor M5 is turned on, the voltage level on the terminal Q1 is discharged to the low voltage level VGL+|Vth| from the high voltage level VGH at time t5. When the voltage level on the terminal Q1 is the low voltage level VGL+|Vth|, the transistors M6 and M7 are turned on. The transistor M7 may charge the terminal B1 to change the voltage level on the terminal B1 to the high voltage level VGH from the low voltage level VGL+|Vth|. When the voltage level on the terminal B1 is the high voltage level VGH, the transistor M3 is turned off. The transistor M6 may charge the output terminal (i.e. the drain of the transistor M3) such that the voltage level of the output pulse signal SN[n] may be kept on the high voltage level VGH. When the voltage level on the output terminal is the high voltage level VGH, the transistor M4 is turned off. Accordingly, the voltage level of the output pulse signal SN[n] may be kept stable (i.e. the high voltage level VGH) during the third phase P3. According to some embodiments, at time t6 of the third phase P3, the voltage level of the second clock signal CK2 is changed to the high voltage level VGH from the low voltage level VGL. The transistors M1 and M2 may be turned off during the third phase P3.

According to some embodiments, after the third phase P3, the registering circuit 200 repeats the above-mentioned operations of the phases P1, P2, and P3 to generate the next output pulse signal based on the next input pulse signal. In other words, the pulse 602 of the second clock signal CK2 repeatedly discharges the voltage level on the terminal Q1 to the low voltage level VGL+|Vth| for ensuring the voltage level of the output pulse signal SN[n] kept on the high voltage level VGH in every phase P3. Moreover, in every phase P2, the transistor M4 is turned on to keep the voltage level on the terminal Q1 on the high voltage level VGH to continue turning off the transistors M6 and M7 such that the transistors M6 and M7 may not affect the operation of the transistor M3.

According to some embodiments, the clock signals CK1, CK2, and CK3 may be arranged to input to the drain of the transistor M3 and gate of the transistor M5 of each of the registering circuits 102_1-102_n by following the order of CK1 and CK2, CK2 and CK3, CK3 and CK1, and so on. For example, during the first phase P1, the pulse of the input pulse signal SN[n−2] of the registering circuit 102_n−1 is locked to the clock signal CK3, which is the clock signal inputted to the drain of the transistor M3 of the previous registering circuit 102_n−2. During the second phase P2, the pulse of the output pulse signal SN[n−1] of the registering circuit 102_n−1 is locked to the clock signal CK1, which is the clock signal inputted to the drain of the transistor M3 of the next registering circuit 102_n. During the third phase P3, the pulse of the output pulse signal SN[n] of the registering circuit 102_n is locked to the clock signal CK2, which is the clock signal inputted to the drain of the transistor M3 of the registering circuit 102_n.

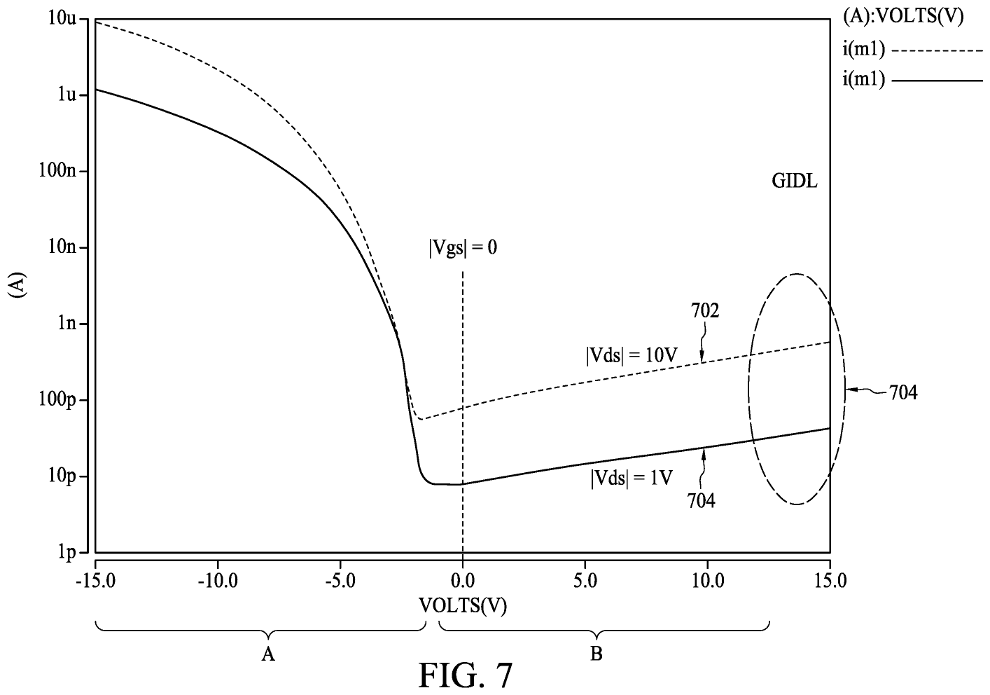

FIG. 7 is a diagram illustrating the leakage current of a transistor in accordance with some embodiments. The transistor is turned on in region A and turned off in region B. The curve 702 represents the current of the transistor when the voltage difference between the drain and the source of the transistor is 10V, i.e. |Vds|=10. The curve 704 represents the current of the transistor when the voltage difference between the drain and the source of the transistor is IV, i.e. |Vds|=1. According to FIG. 7, when the voltage difference between the gate and the source of the transistor M1 is zero, i.e. |Vgs|=0, the transistor may have the minimum leakage current. However, when the voltage difference between the gate and the source of the transistor M1 continuously increases in the region B, the leakage current of the transistor also increases. When the voltage difference between the gate and the source of the transistor M1 enters the region 704, the transistor may have serious or relatively large leakage current, i.e. the Gate Induced Drain Leakage (GIDL) current. In other words, to make a turn-off transistor to have the minimum leakage current, the voltage difference between the gate and the source of the transistor should be zero, i.e. |Vgs|=0.

According to some embodiments, the transistors M1 and M5 are configured to be diode-connected transistor. For a diode-connected transistor, the gate is connected to the drain. When the transistors M1 and M5 are diode-connected, the current leakage of the transistors M1 and M5 may be greatly reduced. Specifically, for the example of the transistor M1, when the gate as well as the drain of the transistor M1 is connected to the low voltage level VGL to turn on the transistor M1, the transistor M1 may output a low voltage level (i.e. VGL+|Vth|) on the source (i.e. the terminal B1) of the transistor M1. When the gate as well as the drain of the transistor M1 is connected to the high voltage level VGH to turn off the transistor M1, the voltage difference between the gate and the source of the transistor M1 is zero, i.e. |Vgs|=0. As described in FIG. 7, when the voltage difference between the gate and the source of the transistor M1 is zero, the transistor M1 (and M5) may not induce the Gate Induced Drain Leakage (GIDL) current when the transistor M1 is turned off. Accordingly, the current leakage of the registering circuit 200 may be greatly reduced.

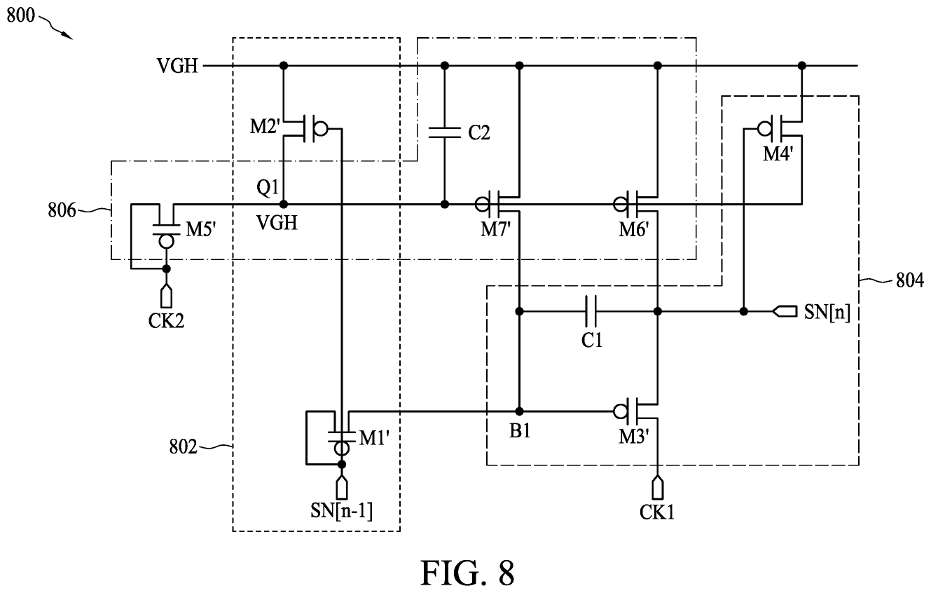

FIG. 8 is a diagram illustrating a registering circuit 800 in accordance with some embodiments of the present invention. The registering circuit 800 may be the implementation of each of the registering circuits 102_1-102_n. The registering circuit 800 comprises an input circuit stage 802, an output circuit stage 804, and an auxiliary circuit stage 806. Similar to the registering circuit 200, the input circuit stage 802 is arranged to receive an input pulse signal SN[n−1] during a first phase. The output circuit stage 804 is coupled to the input circuit stage 802 for generating an output pulse signal SN[n] during a second phase following the first phase according to a first clock signal CK1. The auxiliary circuit stage 806 is coupled to the input circuit stage 802 and the output circuit stage 804 for keeping the output pulse signal SN[n] on a predetermined voltage level VGH, e.g. the supply voltage level, during a third phase following the second phase according to a second clock signal CK2 different from the first clock signal CK1.

According to some embodiments, the input circuit stage 802 comprises a first transistor M1′ and a second transistor M2′. The connection between the transistor M1′ and the transistor M2′ is similar to the connection between the transistor M1 and the transistor M2 of the input circuit stage 202 in FIG. 1, and the detailed description is omitted here for brevity.

The output circuit stage 804 comprises a first transistor M3′, a second transistor M4′, and a capacitive device C1. The capacitive device C1 may be a capacitor. The connection between the transistor M3′ and the transistor M4′ is similar to the connection between the transistor M3 and the transistor M4 of the output circuit stage 204 in FIG. 1, and the detailed description is omitted here for brevity. In comparison to the output circuit stage 204, the output circuit stage 804 further comprises the capacitive device C1. The capacitive device C1 has a first terminal coupled to the gate of the transistor M3′, and a second terminal coupled to the drain of the transistor M3′.

The auxiliary circuit stage 806 comprises a first transistor M5′, a second transistor M6′, a third transistor M7′, and a capacitive device C2. The capacitive device C2 may be a capacitor. The connection among the transistors M5′, M6′, and M7′ is similar to the connection among the transistors M5, M6, and M7 of the auxiliary circuit stage 206 in FIG. 1, and the detailed description is omitted here for brevity. In comparison to the auxiliary circuit stage 206, the output circuit stage 806 further comprises the capacitive device C2. The capacitive device C2 has a first terminal coupled to the predetermined voltage level VGH, and a second terminal coupled to the gates of the transistors M6′ and M7′.

The operation of the first phase P1 of the registering circuit 800 is similar to the operation of the first phase P1 of the registering circuit 200, and the detailed description is omitted here for brevity.

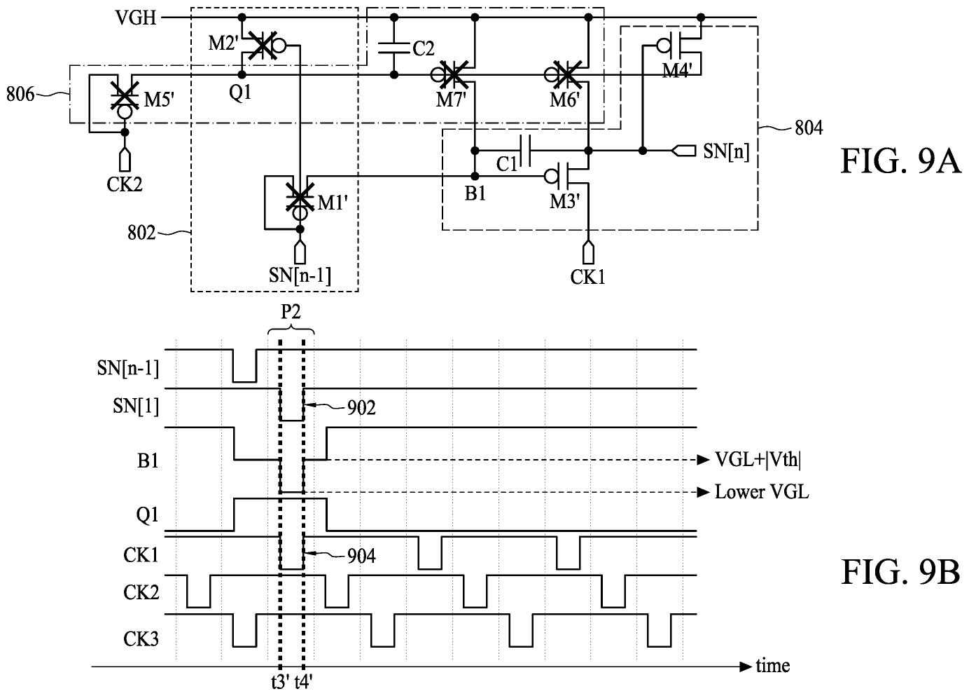

FIG. 9A is a diagram illustrating the registering circuit 800 during the second phase P2 in accordance with some embodiments. FIG. 9B is a timing diagram illustrating the signal waveforms of the registering circuit 800 during the second phase P2 in accordance with some embodiments. During the second phase P2 of the registering circuit 800, the registering circuit 800 is arranged to output the pulse 802 of the output pulse signal SN[n]. According to some embodiments, the pulse 802 is aligned with the pulse 804 of the first clock signal CK1. During the second phase P2, the high voltage level VGH of the input pulse signal SN[n−1] may turn off the transistor M1′ at time t3′. When the transistor M1′ is turned off, the terminal B1 is floating, i.e. the voltage level on the terminal B1 is kept on the low voltage level, i.e. VGL+|Vth|, to continue turning on the transistor M3′ before the time t3′. At time t3′, when the voltage level of the first clock signal CK1 changes to the low voltage level VGL from the high voltage level VGH, the voltage level of the output pulse signal SN[n] is discharged to the low voltage level VGL from the high voltage level VGH. In addition, at time t3′, when the voltage level of the first clock signal CK1 changes to the low voltage level VGL, the voltage level on the terminal B1 is further discharged to a voltage level lower than VGL (i.e. the lower VGL) from the voltage level VGL+|Vth|. According to some embodiments, the capacitive device C1 is coupled between the output terminal (i.e. the output pulse signal SN[n]) and the terminal B1, thus the coupling effect of the capacitive device C1 may cause the voltage level on the terminal B1 to be lower than VGL. Moreover, when the voltage level of the first clock signal CK1 changes to the low voltage level VGL at time t3′, the transistor M4′ is turned on to charge the terminal Q1. Therefore, the voltage level on the terminal Q1 may be kept on the high voltage level VGH to continue turning off the transistors M6′ and M7′ during the phase P2. According to some embodiments, at time t4′ of the second phase P2, the voltage levels of the output pulse signal SN[n] and the first clock signal CK1 are changed to the high voltage level VGH from the low voltage level VGL, and the voltage level on the terminal B1 is changed to the voltage level VGL+|Vth| from the voltage level lower than VGL. The transistors M2′ and M5′ may be turned off during the second phase P2.

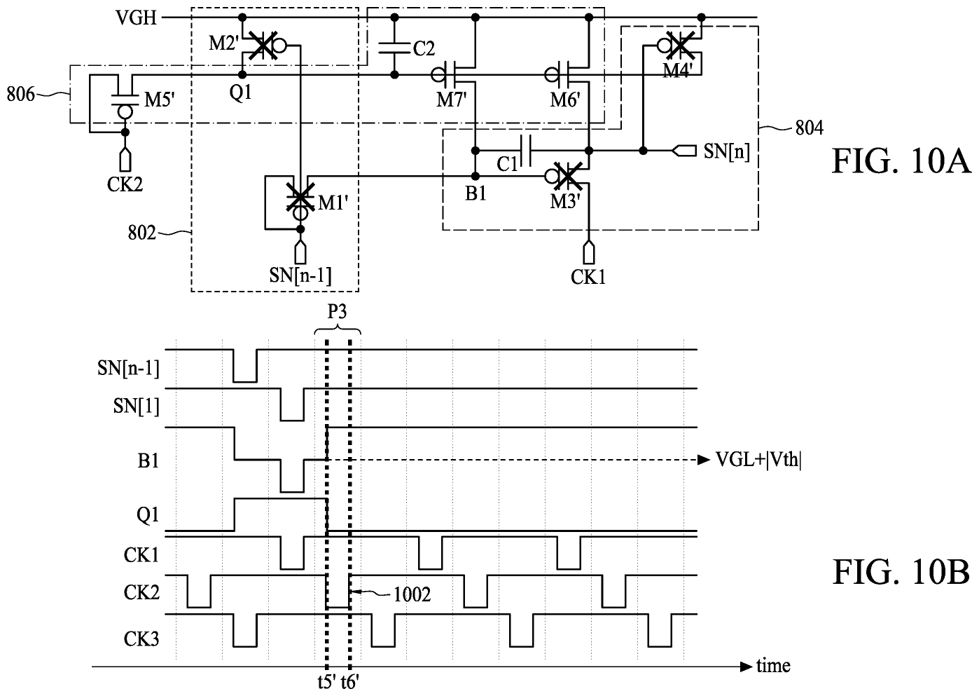

FIG. 10A is a diagram illustrating the registering circuit 800 during the third phase P3 in accordance with some embodiments. FIG. 10B is a timing diagram illustrating the signal waveforms of the registering circuit 800 during the third phase P3 in accordance with some embodiments. During the third phase P3 of the registering circuit 800, the registering circuit 800 is arranged to keep the voltage level of the output pulse signal SN[n] on the high voltage level VGH for a specific time, e.g. a line-time. During the third phase P3, the pulse 1002 of the second clock signal CK2 discharges the voltage level on the terminal Q1 to the low voltage level VGL+|Vth| for ensuring the voltage level of the output pulse signal SN[n] kept on the high voltage level VGH. Specifically, during the third phase P3, the voltage level of the second clock signal CK2 is changed to the low voltage level VGL from the high voltage level VGH to turn on the transistor M5′ at time t5′. When the transistor M5′ is turned on, the voltage level on the terminal Q1 is discharged to the low voltage level VGL+|Vth| from the high voltage level VGH at time t5′. When the voltage level on the terminal Q1 is the low voltage level VGL+|Vth|, the transistors M6′ and M7′ are turned on. The transistor M7′ may charge the terminal B1 to change the voltage level on the terminal B1 to the high voltage level VGH from the low voltage level VGL+|Vth|. When the voltage level on the terminal B1 is the high voltage level VGH, the transistor M3′ is turned off. The transistor M6 may charge the output terminal (i.e. the drain of the transistor M3′) such that the voltage level of the output pulse signal SN[n] may be kept on the high voltage level VGH. When the voltage level on the output terminal is the high voltage level VGH, the transistor M4′ is turned off. Accordingly, the voltage level of the output pulse signal SN[n] may be kept stable (i.e. the high voltage level VGH) during the third phase P3. According to some embodiments, at time t6′ of the third phase P3, the voltage level of the second clock signal CK2 is changed to the high voltage level VGH from the low voltage level VGL. The transistors M1′ and M2′ may be turned off during the third phase P3.

According to some embodiments, the capacitive device C2 may stabilize the low voltage level VGL+|Vth| on the terminal Q1 during the third phase P3 in order to ensure the voltage level of the output pulse signal SN[n] kept on the high voltage level VGH in the third phase P3. Moreover, as the capacitive device C1 is coupled between the output terminal (i.e. the output pulse signal SN[n]) and the terminal B1, the noise at the output terminal (i.e. the noise from the following circuit that couples to the output terminal of the registering circuit 800) may be filtered out by the capacitive device C1. Thus, the noise on the output terminal may not affect the voltage level on the terminal B1 during the third phase P3.

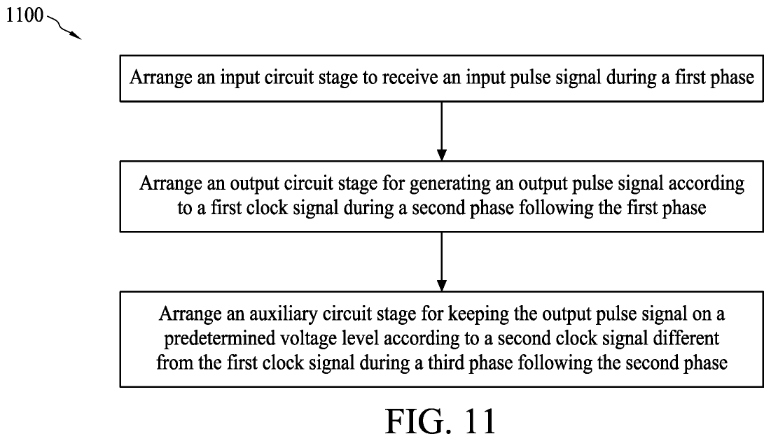

According to some embodiments, the operation of the above-mentioned registering circuits 200 and/or 800 may be summarized into the plurality steps of method 1100. FIG. 11 is a flowchart illustrating a method 1100 for generating an output pulse signal in accordance with some embodiments. The method 1100 comprises operations 1102-1106.

In operation 1102, an input circuit stage (e.g. 202) is arranged to receive an input pulse signal (e.g. SN[n−1]) during a first phase (e.g. P1). The input circuit stage may comprise a diode-connect P-type transistor for receiving the input pulse signal.

In operation 1104, an output circuit stage (e.g. 204) is arranged to output an output pulse signal (e.g. SN[n]) according to a first clock signal (e.g. CK1) during a second phase (e.g. P2) following the first phase. The output circuit stage may comprise a capacitive coupled between the input terminal of the output circuit stage and the output terminal of the output circuit stage for stabilizing the voltage level of the input terminal of the output circuit stage.

In operation 1106, an auxiliary circuit stage (e.g. 206) is arranged to keep the voltage level of the output pulse signal (e.g. SN[n]) on a predetermined voltage level according to a second clock signal (e.g. CK1) different from the first clock signal during a third phase (e.g. P3) following the second phase. The auxiliary circuit stage may comprise a diode-connect P-type transistor for receiving the second clock signal. The auxiliary circuit stage may comprise a capacitive coupled between the supply voltage and a terminal (e.g. Q1) for stabilizing the voltage level of the output pulse signal.

Briefly, the present embodiments provides a shift register having a plurality registering circuits. The shift register may generate a plurality of highly stable shifting pulse signals (e.g. SN[l]-SN[n]). The shifting pulse signals may be used to scan the row switches of a display panel system or used to control the pixels of the display panel. Furthermore, each of the registering circuits is implemented by the same type MOSFETs, i.e. either using seven P-type MOSFETs or seven N-type MOSFETs. When the registering circuits are implemented by the same type MOSFETs, the masks used to fabricate the shift register may be reduced.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A circuit, comprising:
an input circuit stage, arranged to receive an input pulse signal during a first phase;
an output circuit stage, coupled to the input circuit stage for generating an output pulse signal during a second phase following the first phase according to a first clock signal; and
an auxiliary circuit stage, coupled to the input circuit stage and the output circuit stage for keeping the output pulse signal on a predetermined voltage level during a third phase following the second phase according to a second clock signal different from the first clock signal.

2. The circuit of claim 1, wherein the input pulse signal has a first pulse with a first pulse width in the first phase, the first clock signal has a second pulse with a second pulse width in the second phase, and the second pulse width is equal to the first pulse width.

3. The circuit of claim 1, wherein the first clock signal has a first pulse with a first pulse width in the second phase, the output pulse signal has a second pulse with a second pulse width in the second phase, and the second pulse width is equal to the first pulse width.

4. The circuit of claim 1, wherein the first clock signal has a first pulse with a first pulse width in the second phase, the second clock signal has a second pulse with a second pulse width in the third phase, and the second pulse width is equal to the first pulse width.

5. The circuit of claim 1, further comprising:
a capacitive device, coupled between the output circuit stage and the input circuit stage.

6. The circuit of claim 1, further comprising:
a capacitive device, coupled between the auxiliary circuit stage and a reference voltage.

7. The circuit of claim 1, wherein the input circuit stage comprises:
a first transistor, having a controlling terminal receiving the input pulse signal, a first connecting terminal coupled to the controlling terminal, and a second connecting terminal coupled to the output stage; and
a second transistor, having a controlling terminal receiving the input pulse signal, a first connecting terminal coupled to a reference voltage, and second connecting terminal coupled to the auxiliary circuit stage.

8. The circuit of claim 7, wherein the output circuit stage comprises:
a third transistor, having a controlling terminal coupled to the second connecting terminal of the first transistor, a first connecting terminal receiving the first clock signal, and a second connecting terminal for outputting the output pulse signal; and
a fourth transistor, having a controlling terminal coupled to the second connecting terminal of the third transistor, a first connecting terminal coupled to the reference voltage, and a second connecting terminal coupled to the auxiliary circuit stage.

9. The circuit of claim 8, wherein the output circuit stage further comprises:
a capacitive device, having a first terminal coupled to the controlling terminal of the third transistor, and a second terminal coupled to the second connecting terminal of the third transistor.

10. The circuit of claim 8, wherein the auxiliary circuit stage comprises:
a fifth transistor, having a controlling terminal receiving the second clock signal, a first connecting terminal coupled to the controlling terminal, and a second connecting terminal coupled to the second connecting terminal of the fourth transistor;
a sixth transistor, having a controlling terminal coupled to the second connecting terminal of the fifth transistor, a first connecting terminal coupled to the reference voltage, and a second connecting terminal coupled to the controlling terminal of the third transistor; and
a seventh transistor, having a controlling terminal coupled to the second connecting terminal of the fifth transistor, a first connecting terminal coupled to the reference voltage, and a second connecting terminal coupled to the second connecting terminal of the third transistor.

11. The circuit of claim 10, wherein the auxiliary circuit stage further comprises:
a capacitive device, having a first terminal coupled to the controlling terminal of the sixth transistor, and a second terminal coupled to the reference voltage.

12. A shift register, comprising:
a first circuit, arranged to generate a first output pulse signal according to an input pulse signal, a first clock signal, and a second clock signal, wherein the first circuit comprises:
a first input circuit stage, arranged to receive the input pulse signal during a first phase;
a first output circuit stage, coupled to the first input circuit stage for generating the first output pulse signal during a second phase following the first phase according to the first clock signal; and
a first auxiliary circuit stage, coupled to the first input circuit stage and the first output circuit stage for keeping the first output pulse signal on a predetermined voltage level during a third phase following the second phase according to the second clock signal different from the first clock signal; and
a second circuit, arranged to generate a second output pulse signal according to the fist output pulse signal, the first clock signal, and the second clock signal.

13. The shift register, wherein the second circuit comprises:
a second input circuit stage, arranged to receive the first output pulse signal during the second phase;
a second output circuit stage, coupled to the second input circuit stage for generating the second output pulse signal during the third phase following the second phase according to the first clock signal; and
a second auxiliary circuit stage, coupled to the second input circuit stage and the second output circuit stage for keeping the second output pulse signal on the predetermined voltage level during a fourth phase following the third phase according to the second clock signal different.

14. The shift register circuit of claim 12, wherein the first input circuit stage comprises:
a first transistor, having a controlling terminal receiving the input pulse signal, a first connecting terminal coupled to the controlling terminal, and a second connecting terminal coupled to the first output stage; and
a second transistor, having a controlling terminal receiving the input pulse signal, a first connecting terminal coupled to a reference voltage, and second connecting terminal coupled to the first auxiliary circuit stage.

15. The shift register of claim 14, wherein the first output circuit stage comprises:
a third transistor, having a controlling terminal coupled to the second connecting terminal of the first transistor, a first connecting terminal receiving the first clock signal, and a second connecting terminal for outputting the first output pulse signal; and
a fourth transistor, having a controlling terminal coupled to the second connecting terminal of the third transistor, a first connecting terminal coupled to the reference voltage, and a second connecting terminal coupled to the first auxiliary circuit stage.

16. The shift register of claim 15, wherein the first auxiliary circuit stage comprises:
a fifth transistor, having a controlling terminal receiving the second clock signal, a first connecting terminal coupled to the controlling terminal, and a second connecting terminal coupled to the second connecting terminal of the fourth transistor;
a sixth transistor, having a controlling terminal coupled to the second connecting terminal of the fifth transistor, a first connecting terminal coupled to the reference voltage, and a second connecting terminal coupled to the controlling terminal of the third transistor; and
a seventh transistor, having a controlling terminal coupled to the second connecting terminal of the fifth transistor, a first connecting terminal coupled to the reference voltage, and a second connecting terminal coupled to the second connecting terminal of the third transistor.

17. A method, comprising:
arranging an input circuit stage to receive an input pulse signal during a first phase;
arranging an output circuit stage for generating an output pulse signal according to a first clock signal during a second phase following the first phase; and
arranging an auxiliary circuit stage for keeping the output pulse signal on a predetermined voltage level according to a second clock signal different from the first clock signal during a third phase following the second phase.

18. The method of claim 17, further comprising:
arranging a capacitive device to couple between the output circuit stage and the input circuit stage.

19. The method of claim 17, further comprising:
arranging a capacitive device to couple between the auxiliary circuit stage and a reference voltage.

20. The method of claim 17, wherein the input pulse signal has a first pulse with a first pulse width in the first phase, the first clock signal has a second pulse with a second pulse width in the second phase, and the second pulse width is equal to the first pulse width.
